(19) United States
(12) Patent Application Publication
(10) Pub. No.: US 2010/0289150 A1
(43) Pub. Date: Nov. 18, 2010

(54) Semiconductor device, designing method for semiconductor device, computer-readable medium, and manufacturing method for semiconductor device

(75) Inventor: Nobuaki Hamanaka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 12/662,906

(22) Filed: May 11, 2010

(30) Foreign Application Priority Data
May 12, 2009 (JP) 2009-115819

(51) Int. Cl. H01L 23/522; G06F 17/50; H01L 21/768

(52) U.S. Cl. 257/773; 716/10; 438/622; 257/E21.575; 257/E23.142

(57) ABSTRACT

A designing method for a semiconductor device includes: determining a placement of metal wirings to be connected to contact holes and a placement of through-holes for preparing the contact holes. The determining step includes: specifying areas in one of the metal wirings to be exposed by the through-holes, specifying a capacitance of the metal wirings, and determining the placement of the metal wirings such that damage to the areas is suppressed in a case where electric charges accumulated in the capacitance are transferred from one of the metal wirings to a polar solvent through the areas.

### INCORPORATION BY REFERENCE

This application is based upon and claims the benefit of priority from Japanese patent application No. 2009-115819 filed on May 12, 2009, the disclosure of which is incorporated herein in its entirety by reference.

### BACKGROUND OF THE INVENTION

1. Field of the Invention

The present invention relates to a semiconductor device, a designing method for the semiconductor device, and a semiconductor design supporting program that supports designing the semiconductor device.

2. Description of Related Art

As a technique related to manufacturing of a semiconductor device including a multilayer wiring layer, a damascene method is known. In the damascene method, an opening portion (through-hole) is formed through an interlayer film provided on a circuit board by a method such as dry etching or plasma asking. After the opening portion (through-hole) is formed, residue formed during the etching process is removed by cleaning by using a chemical solution. Then, a metal film such as Cu film is deposited by a sputtering method, plating method, or the like. Subsequently, planarization is performed by a CMP method or the like.

Also, as another technique related to a manufacturing of a semiconductor device including a multilayer wiring layer, a dual damascene method is known. In the dual damascene method, just above a lower layer wiring, an interlayer film and a stopper film having an etching rate different from an etching rate of the interlayer film is deposited. Then, a through-hole is first opened in the interlayer film by etching, and subsequently a resist or the like is coated to planarize a wafer surface. After the planarization is completed, a wiring pattern is formed by a lithography technique, and then wiring trench etching is performed on the interlayer film. After the wiring trench etching is completed, the stopper film at the bottom of the through-hole is etched to form an opening to the lower layer wiring. On the basis of such steps, the through-hole and wiring trench are simultaneously formed. After that, the through-hole and the wiring trench are filled with metal film by depositing the metal film and carrying out the CMP. By repeating such manufacturing steps, the semiconductor device having the multilayer wiring layer on a semiconductor substrate is formed.

FIG. 1 is a cross-sectional view illustrating a state of a member in a conventional semiconductor device manufacturing process. FIG. 1 illustrates the state of the member that is formed with through-holes 151 on a metal wiring using Cu (copper) as a material (hereinafter referred to as a Cu wiring 104). It is assumed that FIG. 1 illustrates the through-holes 151 which is manufactured by a dual damascene method and is in the state where a subsequent cleaning step is completed.

As illustrated in FIG. 1, in a step of forming the through-holes 151, on the Cu wiring 104, an etching stopper film 103, interlayer film 102, and CMP sacrificial interlayer film 101 are sequentially formed. Then, by dry etching, the interlayer film 102 and CMP sacrificial interlayer film 101 are selectively removed to form the through-holes 151 on the Cu wiring 104. At this time, most of the through-holes 151 are opened to the etching stopper film 103, and therefore the underlying Cu wiring 104 is not exposed. The etching stopper film 103 is removed in a subsequent step.

FIGS. 2A and 2B are diagrams illustrating states of a semiconductor device manufacturing process in the case where defects occur on a surface of the Cu wiring 104 or in the etching stopper film 103. As illustrated in FIG. 2A, in a step of forming the underlying Cu wiring 104, due to an aggregation phenomenon or surface reaction on the surface of the Cu wiring 104, local micro-protrusions 105 may be generated. Also, as illustrated in FIG. 2B, at the time of deposition of the etching stopper film 103, micro-voids 106 may be formed in the film.

FIG. 3 is a cross-sectional view exemplifying a state of the member in the case where a defect occurs on the surface of the Cu wiring 104 or in the etching stopper film 103, and the micro-protrusion 105 is formed at a site where the defect occurs. As illustrated in FIG. 3, a through-hole 151 formed on the micro-protrusion 105 on the surface of the Cu wiring 104, or on the micro-void 106 formed in the etching stopper film 103 (hereinafter referred to as a specific through-hole 152) exhibits a state where up to the etching stopper film 103 on the Cu wiring 104 is simultaneously etched, differently from a normal through hole opening 151, and the Cu wiring 104 is exposed.

Subsequently, to remove etching residue generated during the dry etching step of the through-holes, cleaning of the semiconductor device is performed. At this time, a typical cleaning method is that the cleaning is first performed with a chemical solution mainly including a polar solvent such as water, and then the semiconductor device is rinsed with pure water or the like, and subsequently dried.

FIG. 4 is a cross-sectional view illustrating a cross section of the through-holes immediately after the cleaning of the member illustrated in FIG. 3. As illustrated in FIG. 4, in the specific through-hole 152, the Cu wiring is locally exposed. When the specific through-hole 152 is rinsed with pure water or the like, copper composed of the Cu wiring 104 may be eluted in the pure water.

Referring to FIG. 4, in a region 153, copper is eluted. Also, the copper eluted from the region 153 accumulates onto the interlayer film, and remains as residue 154. Further, after drying, the Cu wiring in the through-hole (in the region 153) may be likely to be oxidized.

As a means adapted to solve the above-described phenomenon, for example, there is known a technique described in Patent literature 1 (Japanese patent publication No. JP2003-124316A (related to, US2003027418 (A1), US2003134507(A1)). Patent literature 1 describes a semiconductor device manufacturing method. In the cleaning step of this technique, prior to cleaning with pure water or organic remover that is a polar solvent, an opening is cleaned with a non-water based solvent. By applying this technique, electrical charges accumulated in an interlayer film in a plasma atmosphere are moved to the non-water based solvent side to thereby remove the electrical charges from the interlayer film.

We have now discovered the following facts.

As described in Patent literature 1, in the case of opening through-holes on a wiring layer with a large area, as an area of the wiring layer is increased, a phenomenon in which metal constituting the wiring layer is eluted from the through-holes is more significantly recognized. In the case where an area of the wiring layer is the same, as the number of through-holes to be connected to the wiring layer is decreased, or as an opening diameter of the through-holes is decreased, the phenomenon of the metal elution is more significantly recognized.

In particular, if there is a through-hole that is locally opened, it is difficult to keep an area of the wiring layer, which is an underlying layer to be connected to the through-hole, at a certain value or less with respect to the number of through-holes where an underlying wiring is exposed.

Therefore, a semiconductor device and a design method for the semiconductor device is desired, which suppress a wiring layer from being eluted, and oxidized in a manufacturing step of cleaning following a formation of the wiring layer.

### SUMMARY

The present invention seeks to solve one or more of the above problems, or to improve upon those problems at least in part.

In one embodiment, a designing method for a semiconductor device includes: determining a placement of metal wirings to be connected to contact holes and a placement of through-holes for preparing the contact holes. The determining step includes: specifying areas in one of the metal wirings to be exposed by the through-holes; specifying a capacitance of the metal wirings; and determining the placement of the metal wirings such that damage to the areas is suppressed in a case where electric charges accumulated in the capacitance are transferred from one of the metal wirings to a polar solvent through the areas.

In another embodiment, a computer-readable medium including a computer program comprising code operable to control a computer as a semiconductor device designing apparatus, the code includes: determining a placement of metal wirings to be connected to contact holes and a placement of through-holes for preparing the contact holes. The determining step includes: specifying areas in one of the metal wirings to be exposed by the through-holes; specifying a capacitance of the metal wirings; and determining the placement of the metal wirings such that damage to the areas is suppressed in a case where electric charges accumulated in the capacitance are transferred from one of the metal wirings to a polar solvent through the areas.

In another embodiment, a manufacturing method for a semiconductor device includes: designing a semiconductor device; and producing the semiconductor device based on the designing. The designing step includes: determining a placement of metal wirings to be connected to contact holes and a placement of through-holes for preparing the contact holes. The determining step includes: specifying areas in one of the metal wirings to be exposed by the through-holes; specifying a capacitance of the metal wirings; and determining the placement of the metal wirings such that damage to the areas is suppressed in a case where electric charges accumulated in the capacitance are transferred from one of the metal wirings to a polar solvent through the areas.

In another embodiment, a semiconductor device includes: contact holes; and metal wirings connected to the contact holes. One of the metal wirings includes areas connected to the contact holes. When each of the areas is defined as a reference area, an area of the one metal wiring is less than 2×10⁶ times as large as the reference area.

In another embodiment, a semiconductor device includes: contact holes; and metal wirings connected to the contact holes. One of the metal wirings includes areas connected to the contact holes. When each of the areas is defined as a reference area, an area of the one metal wiring is equal to or more than 2×10⁶ times as large as the reference area. A sum of a well capacitance of a well to be connected to the metal wirings and a wiring capacitance of the metal wirings to be connected to the well is less than 20 pF.

There can be provided a semiconductor device and a design method for the semiconductor device that suppress a wiring layer from being eluted and oxidized.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating a state of a member in a conventional semiconductor device manufacturing process;

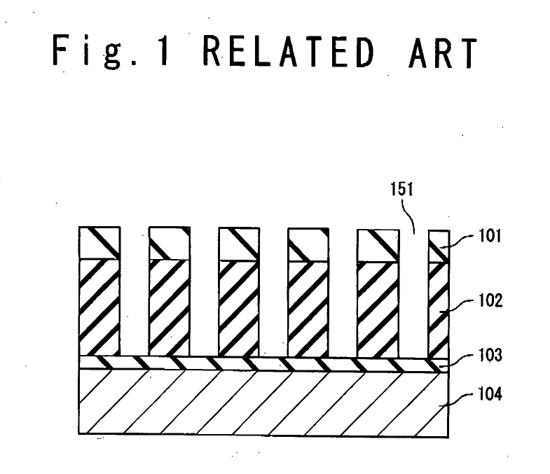

FIGS. 2A and 2B are diagrams illustrating states of the semiconductor device manufacturing process for the case where defects occur on a surface of a Cu wiring or in an etching stopper film;

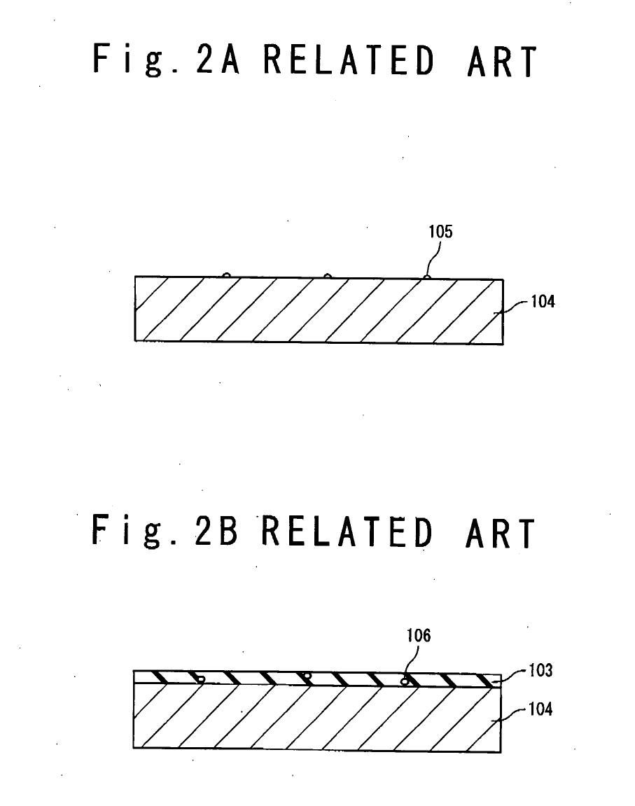

FIG. 3 is a cross-sectional view exemplifying a sate of the member for the case where micro-protrusions are formed on the surface of the Cu wiring or in the etching stopper film;

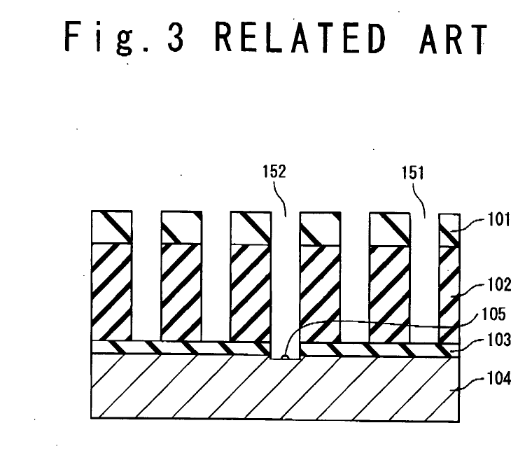

FIG. 4 is a cross-sectional view illustrating a cross section of through-holes immediately after cleaning;

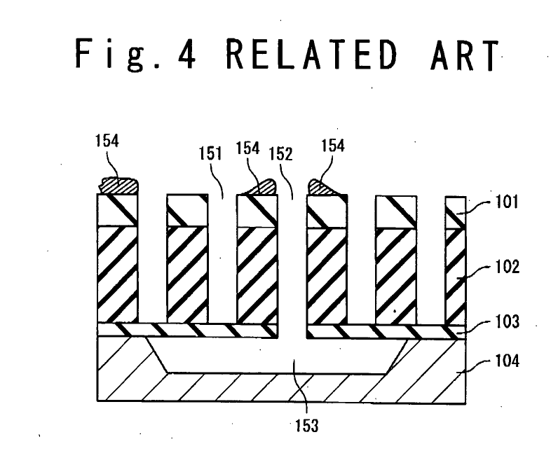

FIG. 5 is a block diagram exemplifying a configuration of a semiconductor design support device in a first embodiment;

FIG. 6 is a flowchart exemplifying an operation of the semiconductor design support device in the embodiment;

FIG. 7 is a cross-sectional view exemplifying a configuration of a semiconductor integrated circuit;

FIG. 8 is a cross-sectional view exemplifying a configuration of a semiconductor integrated circuit that is obtained as a result of performing optimization of a wiring layout;

FIG. 9 is a cross-sectional view exemplifying a configuration of a semiconductor integrated circuit that is obtained as a result of performing optimization of a wiring layout in another manner;

FIG. 10 is a flowchart exemplifying operation of a semiconductor design support device in a second embodiment;

FIG. 11 is a plan view exemplifying a partial layout of a multilayer wiring layer of a semiconductor integrated circuit in the second embodiment;

FIG. 12 is a perspective view exemplifying a state of a semiconductor integrated circuit;

FIG. 13 is a plan view exemplifying a configuration of a multilayer wiring layer to be optimized;

FIG. 14 is a plan view exemplifying a multilayer wiring layer after optimization of a wiring layout is performed;

FIGS. 15A and 15B are perspective views schematically exemplifying layout pattern change;

FIG. 16 is a plan view exemplifying a configuration of a semiconductor integrated circuit in a first comparative example;

FIG. 17 is a cross-sectional view exemplifying a configuration of the semiconductor integrated circuit in the first comparative example;

FIG. 18 is a table representing a change in area of a second metal wiring formed on the same wafer;

FIG. 19 is a graph illustrating a result of evaluations in the first comparative example;

FIG. 20 is a plan view exemplifying a configuration of a semiconductor integrated circuit in a second comparative example;

FIG. 21 is a cross-sectional view exemplifying the semiconductor integrated circuit in the second comparative example;

FIG. 22 is a table exemplifying patterns for evaluating an elution state of a first metal wiring;

FIG. 23 is a graph illustrating a result of evaluations in the second comparative example;

FIG. 24 is a graph illustrating a result of evaluation in the second comparative example;

FIG. 25 is a plan view exemplifying a configuration of a semiconductor integrated circuit in a third comparative example;

FIG. 26 is a diagram exemplifying a configuration of the semiconductor integrated circuit in the third comparative example;

FIG. 27 is a diagram exemplifying a configuration of the semiconductor integrated circuit in the third comparative example;

FIG. 28 is a diagram exemplifying a configuration of the semiconductor integrated circuit in the third comparative example;

FIG. 29 is a diagram exemplifying a configuration of the semiconductor integrated circuit in the third comparative example;

FIG. 30 is a diagram exemplifying a configuration of the semiconductor integrated circuit in the third comparative example;

FIG. 31 is a table exemplifying layout patterns used for evaluations in the third comparative example; and

FIG. 32 is a graph illustrating a result of evaluations in the third comparative example.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

An embodiment of the present invention is described below on the basis of drawings. Note that, in the drawings for describing following embodiments, the same members (and/or portions) are denoted by the same symbols in principle, and their repeat explanation is omitted.

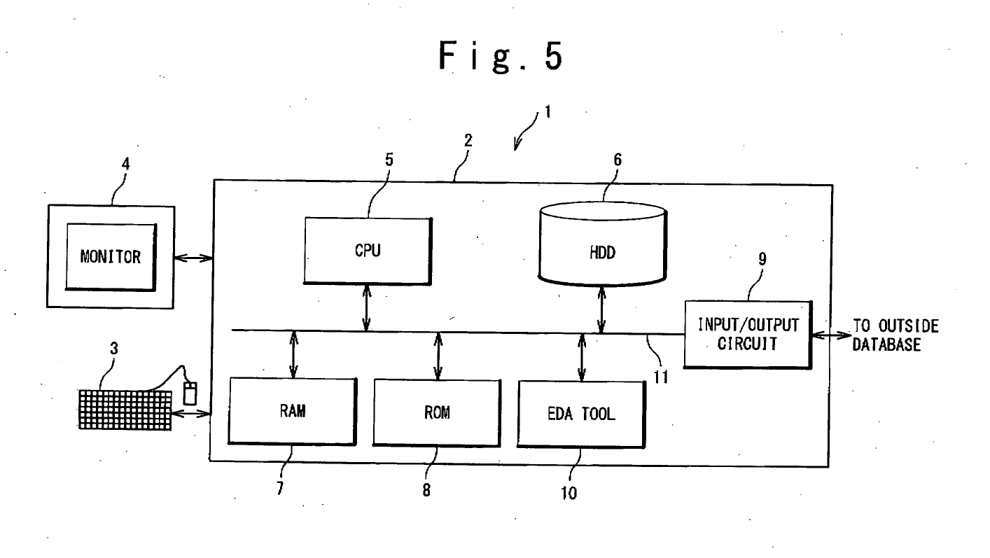

FIG. 5 is a block diagram exemplifying a configuration of a semiconductor design support device 1 in the first embodiment. The semiconductor design support device 1 includes an information processor 2, input device 3, and output device 4. The information processor 2 is a main body part of the device, which is represented by a computer or the like, and performs information processing at high speed. The information processor 2 is provided with a five basic functions, i.e., input, storage, calculation, control, and output. The information processor 2 performs information processing according to a procedure described in a program. The input device 3 is a man-machine interface represented by a keyboard or mouse. The output device is a man-machine interface represented by a liquid crystal display, CRT, or the like.

The information processor 2 includes a CPU 5, an HDD (large capacity, storage device) 6, a RAM (Random Access Memory) 7, a ROM (Read Only Memory) 8, an input/output circuit 9, and an EDA tool 10, which are connected to one another through a bus 11.

The CPU 5 controls the various devices provided in the information processor 2, and performs data processing. The CPU 5 interprets and calculates, data received through the input device 3. The CPU 5 outputs a result of the calculation through the output device 4 or the like. The HDD (large capacity storage device) 6 is a storage device having a large capacity that keeps holding data even if a power supply is interrupted. The HDD (large capacity storage device) 6 holds various pieces of data necessary to achieve the present embodiment.

The RAM (Random Access Memory) 7 is a memory device that can freely read and write data. The ROM (Read Only Memory) 8 is a memory device that can read data. Alternatively, the ROM (Read Only Memory) 8 may be a writable ROM (e.g., a nonvolatile memory device such as a flash memory or EEPROM). The input/output circuit 9 controls input/output of data to/from the information processor 2. The EDA (Electronic Design Automation) tool 10 is software for automating and supporting electrical design work such as design work for an electronic device, semiconductor, or the like.

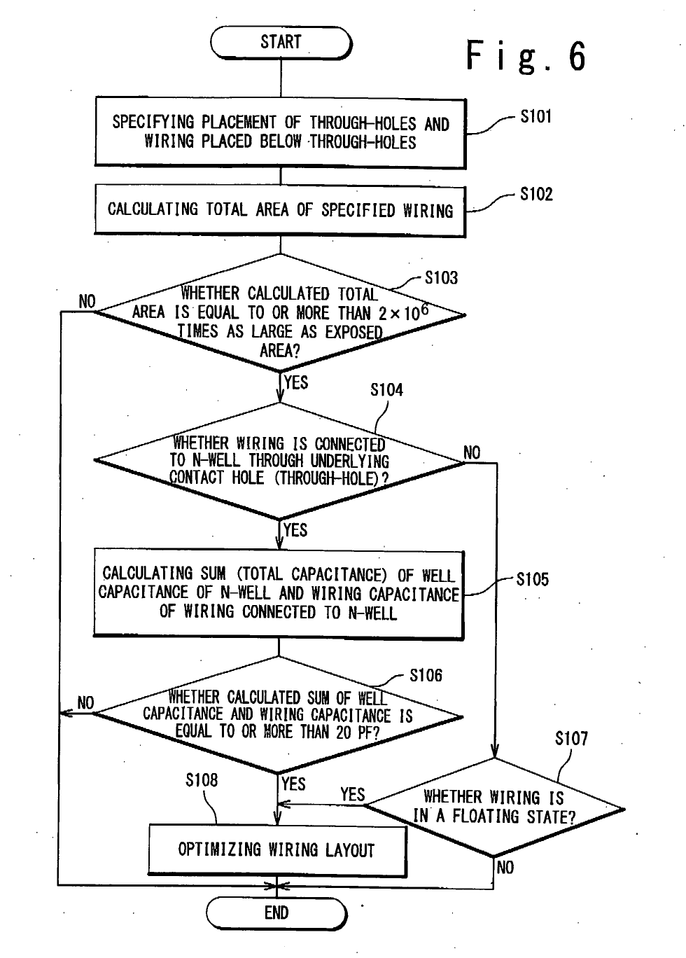

In the following, an operation of the semiconductor design support device 1 in the present embodiment is described. The semiconductor design support device 1 carries out a designing method for a semiconductor device. FIG. 6 is a flowchart exemplifying the operation of the semiconductor design support device 1 in the present embodiment. The operation in the present embodiment is preferably performed at a step of wiring layout in a design of a multilayer wiring semiconductor device to be designed. Also, the operation in the present embodiment is started when the EDA tool 10 reads data necessary for the wiring layout. Here, the wiring layout process includes a step of determining a placement of metal wirings to be connected to contact holes and determining a placement of through-holes for preparing the contact holes. In this step, following steps are included.

In Step S101, through-holes for forming contact holes of multilayer wiring to be designed are specified. Also, wirings having surfaces exposed by the through-holes at the time of manufacturing are specified. This (S101) may be said the step of specifying areas in one of the metal wirings to be exposed by the through-holes. In Step S102, a wiring provided in a specific wiring layer is specified. Also, independently of the number of through-holes to be connected to an upper portion of the wiring, electrically connected portions of the wiring are specified. Then, a total area of the specified portions of the wiring is calculated. At this time, if a wiring of the wiring layer has wiring portions that are electrically isolated to each other by an interlayer insulating film, an area of each of the wiring portions is calculated. This (S102) may be said the step of specifying a capacitance of the metal wirings.

In Step S103, an area of an exposed surface where one through-hole exposes the wiring is calculated. Also, it is determined whether or not the total area calculated in Step S102 is equal to or more than 2×10⁶ times as large as the area of the exposed surface. As a result of the determination, if the total area is equal to or more than 2×10⁶ times as large as the area of one through-hole, the processing flow proceeds to Step S104. If the total area does not exceed 2×10⁶ times as large as the area of the exposed surface, the processing flow is ended.

In Step S104, it is detected whether each of all wells connected with the wiring through underlying through-holes is a p-type or an n-type. Also, it is determined whether or not the connected wells are all n-type wells. As a result of the determination, if the connected wells are all n-type wells, the processing flow proceeds to Step S105. On the other hand, as a result of the determination, if any of the connected wells is not an n-type well, the processing flow proceeds to Step S107.

In Step S105, from a relational expression preliminarily calculated on the basis of a fabrication condition of a semiconductor substrate, an n-type well having the minimum well capacitance is specified, and a value of the capacitance is calculated. Also, a capacitance value associated with a wiring capacitance formed between the wiring and the other wiring is calculated. In Step S106, it is determined whether or not the sum of the well capacitance and the wiring capacitance is equal to or more than 20 pF. As a result of the determination, if the sum is equal to or more than 20 pF, the processing flow proceeds to Step S108. On the other hand, as a result of the determination, if the sum does not exceed 20 pF, the processing flow is ended.

In Step S107, it is determined whether or not the wiring is in a floating state. As a result of the determination, if the wiring is in the floating state, the processing flow proceeds to Step S108. On the other hand, as a result of the determination, if the wiring is not in the floating state, the processing flow is ended. In Step S108, if the sum of the capacitance value of the well and the capacitance value associated with the wiring is equal to or more than 20 pF, or if the wiring is in the floating state, corrective action of the wiring layout is taken to optimize the wiring layout. These (S103-S108) may be said the step of determining the placement of the metal wirings such that damage to the areas is suppressed in a case where electric charges accumulated in the capacitance are transferred from one of the metal wirings to a polar solvent through the areas.

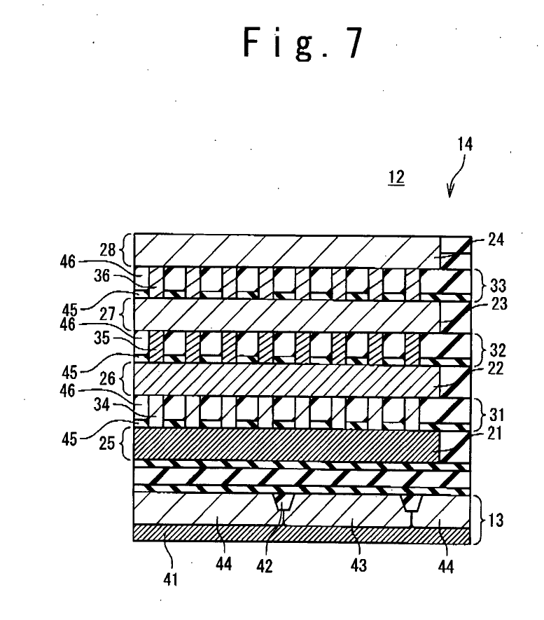

In the following, the optimization of the wiring layout is described. FIG. 7 is a cross-sectional view exemplifying a configuration of a semiconductor integrated circuit 12 to be optimized. The semiconductor integrated circuit 12 includes a multilayer wiring layer 14 including four layers on the circuit substrate 13. The circuit substrate 13 includes a P-well 43 and wells 44 provided on a semiconductor substrate 41. Between the P-well 43 and the well 44, an element isolation 42 is formed.

A first metal wiring 21 is arranged in a first wiring layer 25. A second metal wiring 22 is arranged in a second wiring layer 26. A third metal wiring 23 is arranged in a third wiring layer 27. A fourth metal wiring 24 is arranged in a fourth wiring layer 28. Between the first wiring layer 25 and the second wiring layer 26, a first interlayer insulating layer 31 is provided. Between the second wiring layer 26 and the third wiring layer 27, a second interlayer insulating layer 32 is provided. Between the third wiring layer 27 and the fourth wiring layer 28, a third interlayer insulating layer 33 is provided.

Each of the first interlayer insulating layer 31, the second interlayer insulating layer 32, and the third interlayer insulating layer 33 is formed with a stopper film 45 and an interlayer insulating film 46. The first interlayer insulating layer 31 is formed with a plurality of first contact holes 34 in a plurality of through-holes. The second interlayer insulating layer 32 is formed with a plurality of second contact holes 35 in a plurality of through-holes. The third interlayer insulating layer 33 is formed with a plurality of third contact holes 36 in a plurality of through-holes.

We assume that, on the multilayer wiring layer 14, a bonding structure is formed. As illustrated in FIG. 7, in the case where only the fourth metal wiring 24 is designed to have a large area in the semiconductor integrated circuit 12, the first wiring layer 25, the second wiring layer 26, and the third wiring layer 27 are also often designed to have the same area for the reason of easiness of design.

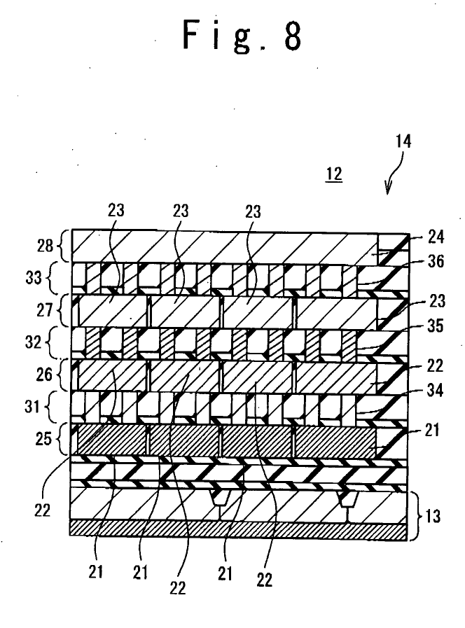

FIG. 8 is a cross-sectional view exemplifying a configuration of the semiconductor integrated circuit 12 that is obtained as a result of performing the above-described optimization of the wiring layout. The multilayer wiring layer 14 after the optimization has been performed is changed in a layout pattern. Referring to FIG. 8, wiring areas of each of the first metal wiring 21, the second metal wiring 22, and the third metal wiring 23 can be reduced to 2×10⁶ times or less as large as the area where a single through-hole exposes a wiring. For example, the first metal wiring 21 in FIG. 7 is divided in to a plurality of metal wirings 21 in FIG. 8. The plurality of metal wirings 21 in FIG. 8 has the same wiring function as that of the first metal wiring 21 in FIG. 7. The wiring area of each metal wiring 21 in FIG. 8 is reduced to 2×10⁶ times or less as large as the area where a single through-hole exposes a wiring.

The corrective action is taken on the pattern design, and thereby obtaining the following effects. That is, even in steps of forming the through-holes for forming the first contact holes 34 in the first interlayer insulating layer 31, the through-holes for forming the second contact holes 35 in the second interlayer insulating layer 32, and the through-holes for forming the third contact holes 36 in the third interlayer insulating layer 33, which are through-holes connecting to upper portions of the respective wiring layers, by dry etching, and then cleaning with pure water or the like, an amount of electrical charges accumulated during the steps can be suppressed. As a result, in each of the interlayer insulating films, even at bottom portions of the through-holes, a current density caused by the electric charges does not reach a current density sufficient to generate an electromotive force for cell reaction causing Cu elution. Therefore the Cu elution at the bottom portions of the through-holes can be prevented. That is, by using this layout design, damage or defect to the wirings can be definitely suppressed.

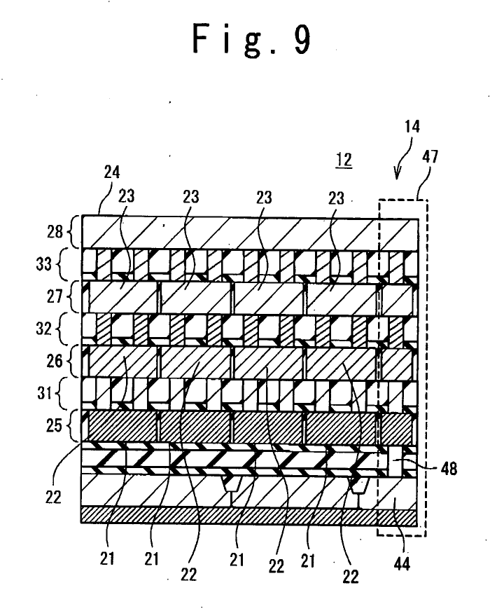

FIG. 9 is a cross-sectional view exemplifying a configuration of the semiconductor integrated circuit 12 that is obtained as a result of performing the above-described optimization of the wiring layout in another manner. As illustrated in FIG. 9, the semiconductor integrated circuit 12 after the optimization has been performed is provided with a diode 47. The diode 47 is a substrate diode conducting to a p-type well, or an n-type well having a capacitance of 20 pF or less. The diode 47 includes a well contact hole 48, and the well contact hole 48 is connected to the well 44.

For example, in a pattern formed of the multilayer wiring layer 14 as illustrated in the above cross-sectional view of FIG. 7, it may be impossible to reduce a wiring area of the fourth metal wiring 24. In such a case, the diode 47 conducted to the substrate through the well 44 is formed. In step of forming the through-holes in the fourth metal wiring 24, electrical charges accumulated in the fourth metal wiring 24 can be immediately transferred to the well 44 through the well contact hole 48. As a result, the Cu elution at the bottom portions of the through-holes can be prevented. Further, the n-type well connected to the wiring may be corrected such that the sum of the capacitance value of the well and the capacitance value associated with the wiring takes a value not exceeding 20 pF.

As described above, when a semiconductor device is cleaned with pure water or the like, metal constituting a wiring layer exposed at bottoms of through-holes is likely to be eluted or oxidized. This phenomenon arises from the fact that, in a step of forming a wiring of the semiconductor device on a semiconductor substrate, if a chemical solution containing a polar solvent such as water comes into contact with an interlayer film that is an insulating film, electrical charges are accumulated in the interlayer film due to contact friction between the chemical solution and the insulating film to cause charge-up.

In particular, in the case of using a nonconductive polar solvent of which the conductive ion content is extremely small, such as pure water, an amount of the charge-up tends to increase. The electrical charges immediately move to a wiring present just below the interlayer film; however, the electrical charges are in contact with pure water (or chemical solution containing water), which is a polar solvent, at the bottoms of the through-holes. For this reason, the accumulated electrical charges are discharged from the bottoms of the through-holes at once. At this time, if a current density caused by the electric charges concentrated at the through-hole bottoms is sufficiently large, an electromotive force sufficient to cause cell reaction is provided, and therefore the metal forming the wiring layer is likely to be ionized, and eluted or oxidized.

Note that, in general, an oxidized metal oxide film (e.g., in the case where the wiring layer is formed of Cu, the oxidized metal oxide film is a CuOx film) has a property of being eluted in organic remover used for cleaning, and therefore if the metal constituting the underlying wiring layer is subjected to the oxidation action at portions where the through-holes are opened, the metal is more likely to be eluted during the cleaning step.

Also, the wiring layer at the through-hole bottoms is eluted and oxidized, a connecting state between the wiring layer and an electrically conductive material filled in the through-holes is deteriorated, which may cause reliability of the semiconductor device to be reduced. In particular, in the case of including the wiring region having the large area wiring layer and the through-holes connected to the large area wiring region, as the area of the wiring region is increased, the phenomenon in which the metal constituting the wiring layer is eluted from the through-hole bottoms is more significantly recognized. Also, in the case where the wiring layer is not connected to the semiconductor substrate in its manufacturing process and therefore in the floating state, or the wiring layer is connected to the semiconductor substrate but has only a high resistance layer such as an n-type well therebetween, this phenomenon is particularly likely to occur. That is, the electrical charges accumulated in the wiring layer is in the state of being discharged only from the through-hole bottoms, the current density caused by the electrical charges at the through-holes are increased at once, and the metal is likely to be eluted and oxidized.

In the present embodiment, first in a design stage of photo-masks, in a design step for a step of opening the through-holes, when an area of a wiring layer to be present in a lower layer of the through-holes, and a type and capacitance of a well to be connected are identified, if the designing is executed such that the wiring area and well capacitance exceed certain values, a correction is made such that the wiring area and well capacitance become equal to or less than the certain values. This enables an amount of electrical charges accumulated in an underlying wiring layer during a cleaning step after through-hole etching to be made equal to a certain value or less, or the electrical charges to be discharged from the well connected to the wiring layer through the semiconductor substrate. Therefore the metal can be prevented from being eluted and oxidized at the exposed through-hole portions. That is, by using this layout design, damage or defect to the wirings can be definitely suppressed.

### Second Embodiment

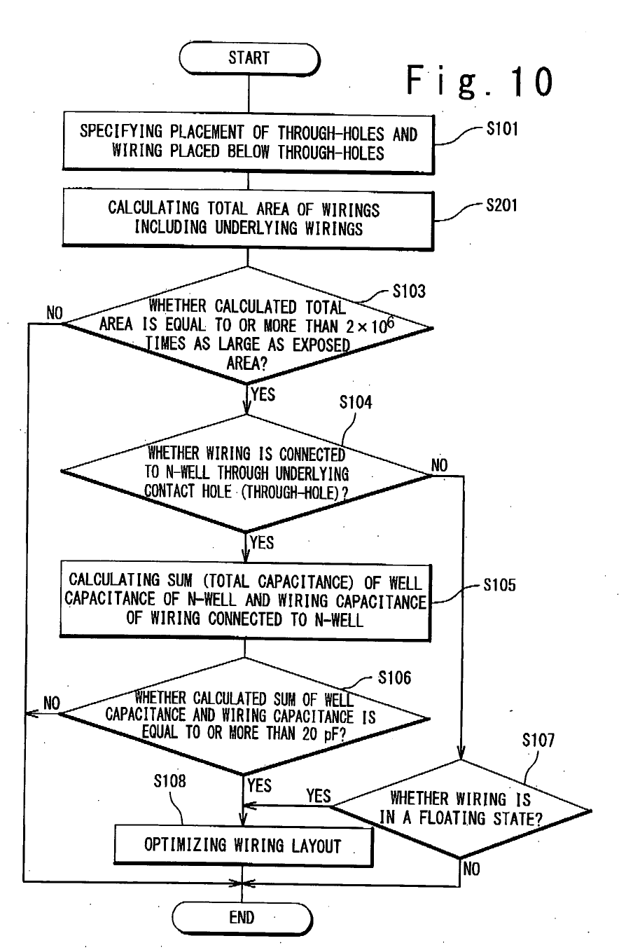

A second embodiment of the present invention is specifically described below referring to the accompanying drawings. FIG. 10 is a flowchart exemplifying an operation of a semiconductor design support device in the second embodiment. The operation in the second embodiment is different from that in the first embodiment, in which wiring layout is optimized with including not only a wiring of a wiring layer of interest but also a wiring provided in a wiring layer underlying the wiring layer of interest.

In Step S101, similarly to the first embodiment, through-holes for forming contact holes of multilayer wiring to be designed are specified. Also, wirings having surfaces exposed by the through-holes at the time of manufacturing are specified.

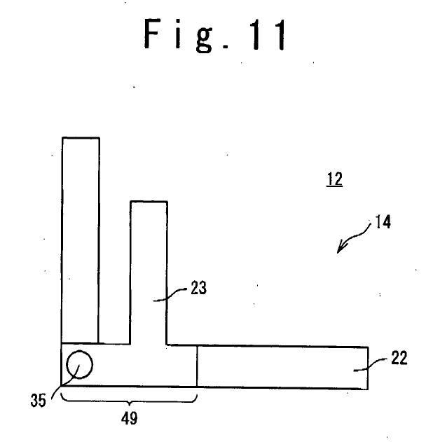

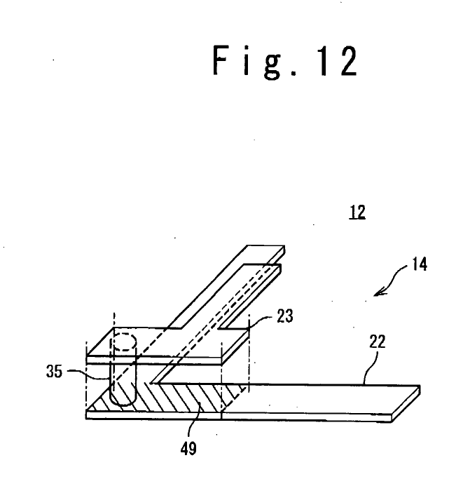

Then, in Step S201, areas of the specified wiring in a wiring layer and a wiring in an underlying wiring layer are calculated. Here, the underlying wiring layer is underlies the wiring layer including the specified wiring. At this time, if there is an overlap between the two wirings in a vertical direction, the areas excluding the overlap area are calculated. FIG. 11 is a plan view exemplifying a partial layout of a multilayer wiring layer 14 of a semiconductor integrated circuit 12 in the second embodiment. FIG. 11 exemplifies the layout in which a second metal wiring 22 and a third metal wiring 23 are connected to each other through a second contact hole 35. As illustrated in FIG. 11, the multilayer wiring layer 14 includes an overlap region 49. FIG. 12 is a perspective view exemplifying a state of the layout of FIG. 11. The overlap region 49 is a portion in which just above the second metal wiring 22, the overlying third metal wiring 23 overlaps. In the second embodiment, we consider the overlap region 49 to be excluded. Subsequently, from Steps S103 to S108, operation is the same as that in the first embodiment.

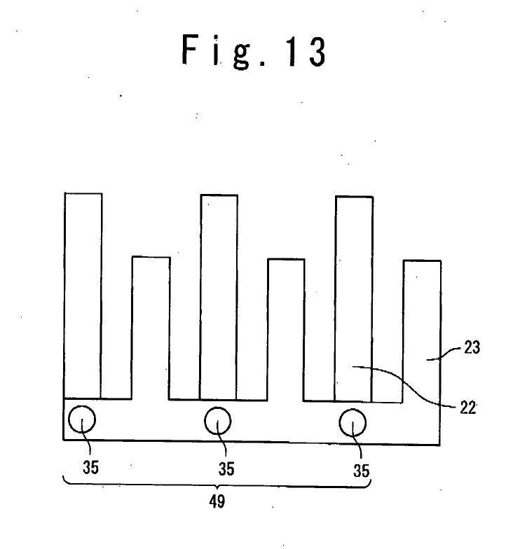

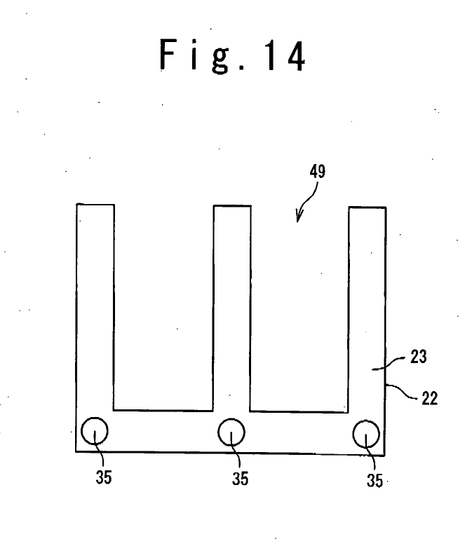

In the following, the optimization of the wiring layout in the second embodiment is described. FIG. 13 is a plan view exemplifying a configuration of the multilayer wiring layer 14 to be optimized. As illustrated in FIG. 13, the second and third metal wirings 22 and 23 are connected to each other through the second contact holes 35. Also, at this time, the overlap region 49 of the second metal wiring 22 is covered by the third metal wiring 23. FIG. 14 is a plan view exemplifying the multilayer wiring layer 14 after the optimization of the wiring layout has been performed. In the optimization of the second embodiment, a layout pattern is changed so as to increase the overlap region 49 in which the third metal wiring 23 covers the second metal wiring 22. By replacing the wiring layout in this manner, a sum of wiring areas of the second metal wiring 22 and the third metal wiring 23 can be reduced in a step of forming through-holes on the third metal wiring 23.

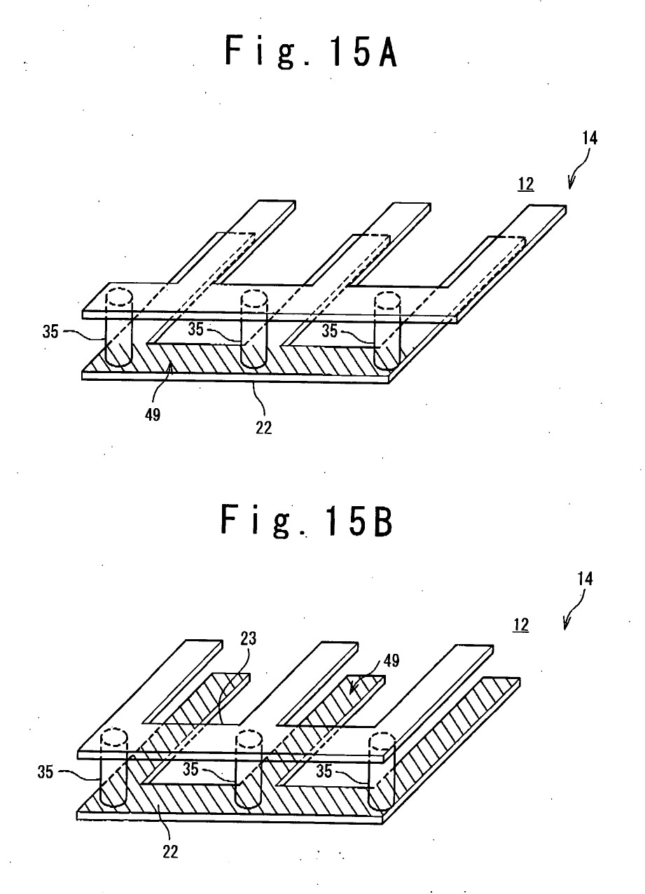

FIGS. 15A and 15B are perspective views schematically exemplifying the above-described layout pattern change. FIG. 15A exemplifies the multilayer wiring layer 14 before the optimization of the wiring layout is performed. FIG. 15B exemplifies the multilayer wiring layer 14 after the optimization of the wiring layout has been performed. As illustrated in FIGS. 15A and 15B, by increasing the overlap region 49, the sum of the wiring areas can be reduced.

That is, if, due to electrical charges charged up by the contact between an interlayer film and a polar solvent, a wiring present in a layer just below the interlayer film is charged, the electrical charges are immediately uniformized within the wiring. Also, a circuit is formed through the polar solvent in contact with a wafer. Therefore influence of charging of the second metal wiring 22, which underlies the third metal wiring 23, through the third metal wiring 23 is ignorable.

By performing the operation of the second embodiment, a total area of wirings constituting a semiconductor device can be reduced to a certain value or less. If a chemical solution containing a polar solvent such as water comes into contact with an interlayer film that is an insulating film, electrical charges are accumulated in the interlayer film due to contact friction between the chemical solution and the insulating film, and subsequently accumulated in an underlying wiring. At this time, if a current density caused by the electrical charges at the time when the electrical charges are discharged from corresponding through-hole bottoms is sufficiently low as compared with the current density generating an electromotive force sufficient to cause a metal elution phenomenon, elution reaction can be prevented. As described above, by performing the operation of the present embodiment, and changing layout so as to limit the wiring area, the electrical charges accumulated in the interlayer film can be discharged without eluting metal constituting a metal wiring at the through-hole bottoms.

### Comparative Examples

In the following, comparative examples for facilitating the understanding of the present invention are described.

### First Comparative Example

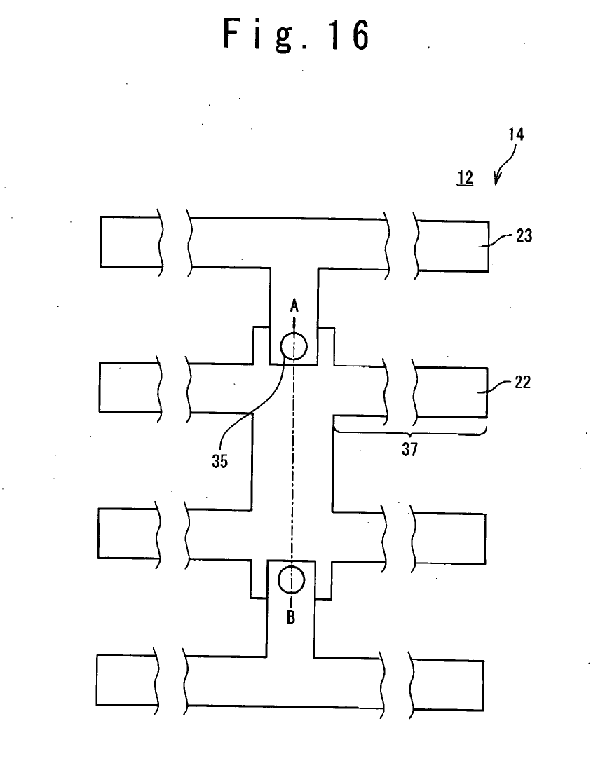

FIG. 16 is a plan view exemplifying a configuration of a semiconductor integrated circuit 12 in a first comparative example. As illustrated in FIG. 16, in a multilayer wiring layer 14 of the semiconductor integrated circuit 12, a second metal wiring 22 and a third metal wiring 23 are connected to each other through a second contact hole 35. Also, the second metal wiring 22 includes a protrusion region 37.

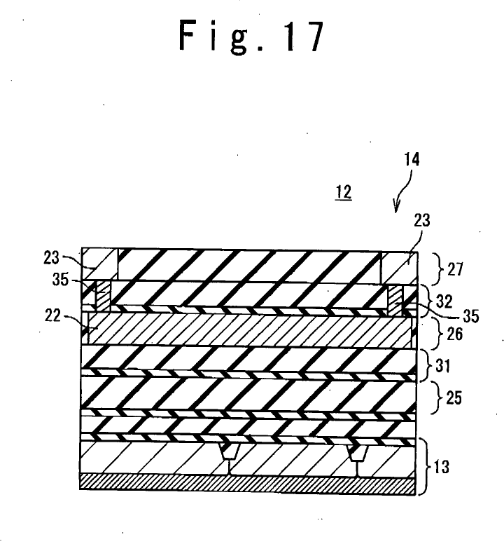

FIG. 17 is a cross-sectional view of the semiconductor integrated circuit 12 along the line A-B in FIG. 16. The second metal wiring 22 of the multilayer wiring layer 14 is connected to the second contact hole 35. The second metal wiring 22 has a large area layout pattern in a floating state. In the first comparative example, there is described an evaluation result in which an elution state of the second metal wiring 22 is evaluated for layout patterns respectively having different conditions with keeping the state of the above layout pattern. Specifically, the elution state of the second metal wiring 22 at the time of chemical solution cleaning and pure water rinsing after etching of through-holes for forming the second contact holes 35 is evaluated.

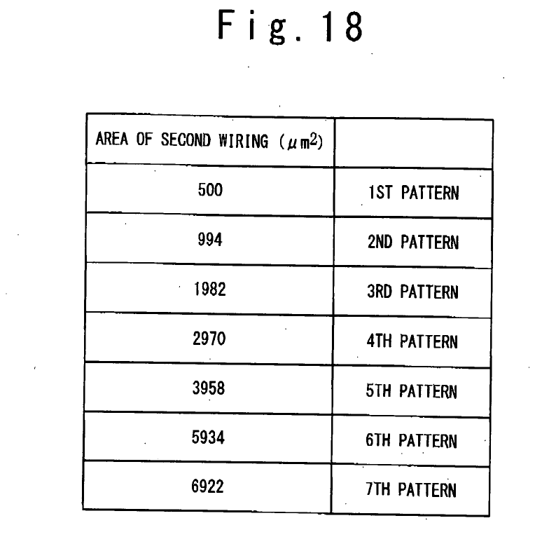

The evaluations are made with use of some layout patterns obtained by adjusting a length of the protrusion region 37 of the second metal wiring 22 to change an area of the second metal wiring 22. FIG. 18 is a table representing the area changes of the second metal wiring 22 formed on the same wafer. Also, in each of the patterns, the two through-holes for forming the second contact holes 35 are configured to be connected in series, and be able to measure electrical conduction by forming a pad through the third metal wiring 23. A percent defective can be taken into account by using electrical resistances of the through-holes for forming the second contact holes 35.

In the evaluations, to improve sensitivity of sensing influence of elution by pure water or the like, an etching stopper film is intentionally removed in a step of etching the through-holes for forming the second contact holes 35, thereby exposing an underlying Cu film. As a cleaning treatment after the etching, amine based remover having a water content of approximately 60% is used as a chemical solution. A cleaning unit having a back chuck system is used such that the chemical solution is sprayed at a flow rate of 2.0 L/min. for 30 seconds and then pure water rinsing is performed for 30 seconds while the wafer is rotated at a rotation speed of 500 rpm; and subsequently the wafer is rotated at a rotation speed of 2000 rpm and thereby dried.

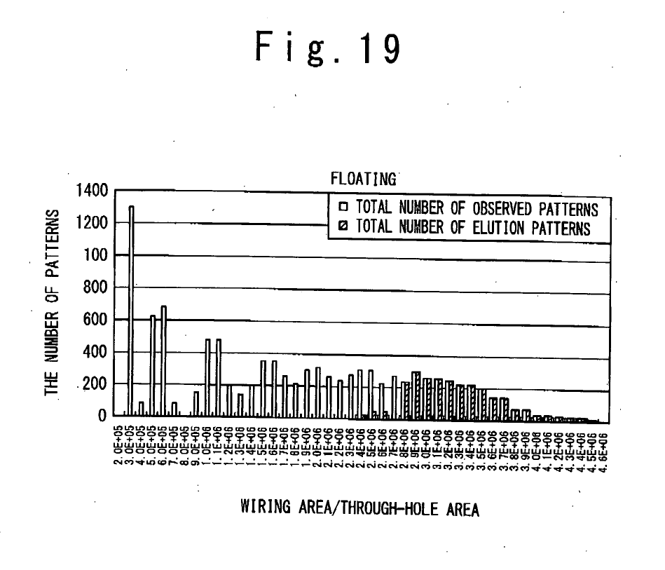

FIG. 19 is a graph illustrating a result of the evaluations based on the above-described method. In FIG. 19, the horizontal axis represents the wiring area, and the vertical axis represents both of the total number of observation patterns and the number of patterns causing the Cu elution. Note that a design value of an area of one of the through-holes for forming the second contact holes 35 is 2.0×10⁻³ μm². In the graph, certain variations of the through-hole area and the wiring area are respectively taken into consideration in diameter and width occurring in lithography, dry etching, and other steps of the manufacturing process, when the wiring area/through-hole area ratio is plotted.

As illustrated in FIG. 19, if the wiring area/through-hole area ratio exceeds 2.6×10⁶, the percent defective is significantly increased. If the semiconductor device is designed without controlling the wiring area/through-hole area ratio, elution of Cu constituting the through-hole bottom wiring due to electrical charges accumulated during the manufacturing process is recognized. If the semiconductor device is designed with controlling the wiring area/through-hole area ratio to 2×10⁶ or less, an amount of the accumulated electrical charges is reduced, and thereby the Cu elution can be prevented.

### Second Comparative Example

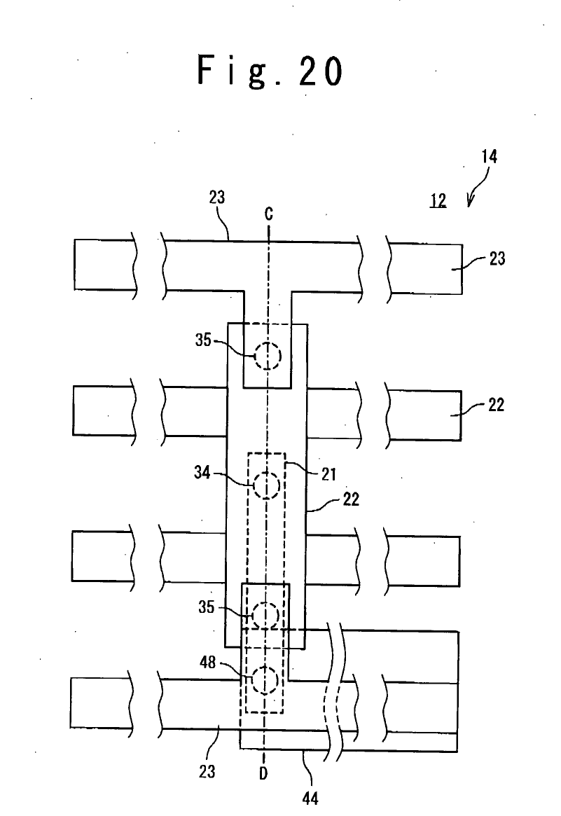

FIG. 20 is a plan view exemplifying a configuration of a semiconductor integrated circuit 12 in a second comparative example. The semiconductor integrated circuit 12 of the second comparative example includes a second metal wiring 22, a third metal wiring 23, and a first metal wiring 21. Also, the first metal wiring 22 and the second metal wiring 23 are connected to each other through a first contact hole 34. The second metal wiring 22 and the third metal wiring 23 are connected to each other through second contact holes 35. Further, the first metal wiring 21 is connected to a well 44 through a well contact hole 48.

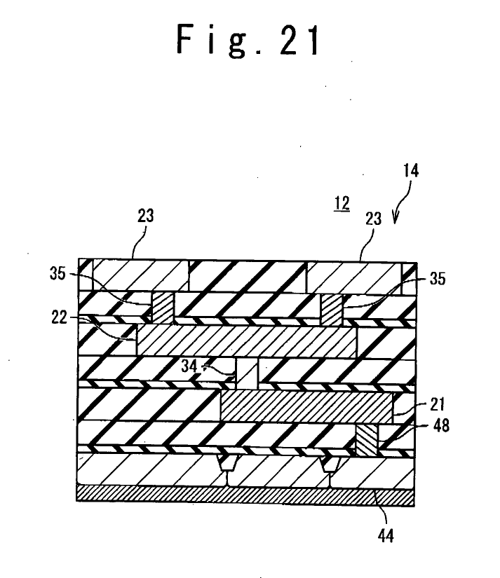

FIG. 21 is a cross-sectional view exemplifying a cross section of the semiconductor integrated circuit 12 in the second comparative example. FIG. 21 exemplifies a cross section along the line C-D in FIG. 20. In the manufacturing steps, the first metal wiring 21 is formed with exposed surfaces that are exposed by through-holes for forming the second contact holes 35. The first metal wiring 21 in a layer just below the through-holes has a large area, and is connected to a semiconductor substrate through the well 44. In the second comparative example, evaluations are made with keeping the above state for each of layout patterns having different conditions.

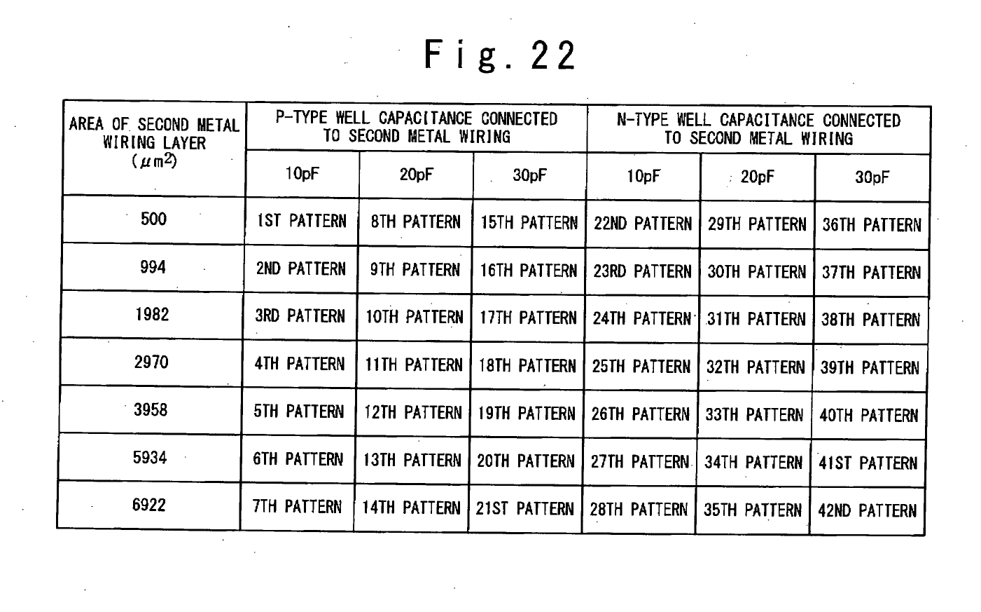

FIG. 22 is a table exemplifying patterns for evaluating an elution state of the first metal wiring 21 for a layout pattern as in the semiconductor integrated circuit 12 of the second comparative example. FIG. 22 is used to evaluate the elution state of the first metal wiring 21 at the time when, after etching of the through-holes, chemical solution cleaning and pure water rinsing are performed.

Note that the patterns used for the test are, similarly to those described in the first comparative example, adapted such that electrical characteristics of the through-holes for forming the second contact holes 35 can be measured, and an etching method for the through-holes and a cleaning method after the etching are the same as those in the first comparative example. Also, as a type of the well 44, the evaluations are made for both of p-type and n-type wells. Also, regarding a well capacitance, as shown in FIG. 22, the patterns respectively having capacitances of 10 pF, 15 pF, and 20 pF are targeted. The case where these layout patterns are formed on one and the same wafer is targeted. Also, regarding an area of the first metal wiring 21 in the layer just below the evaluation target through-holes, the case where the same patterns as those in the first comparative example are formed on one and the same wager is targeted.

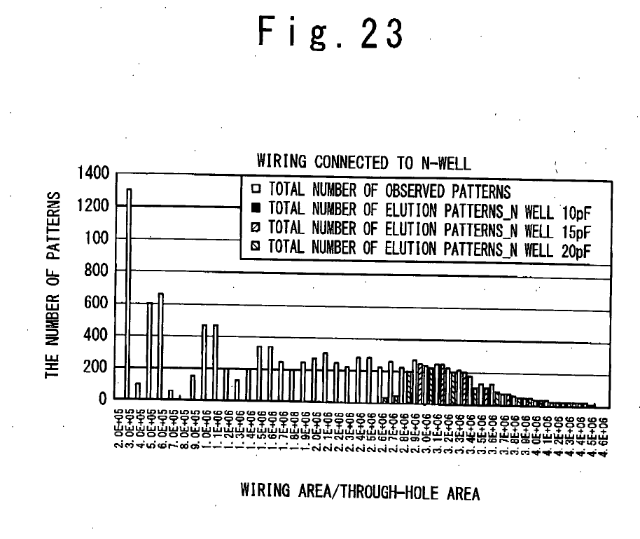

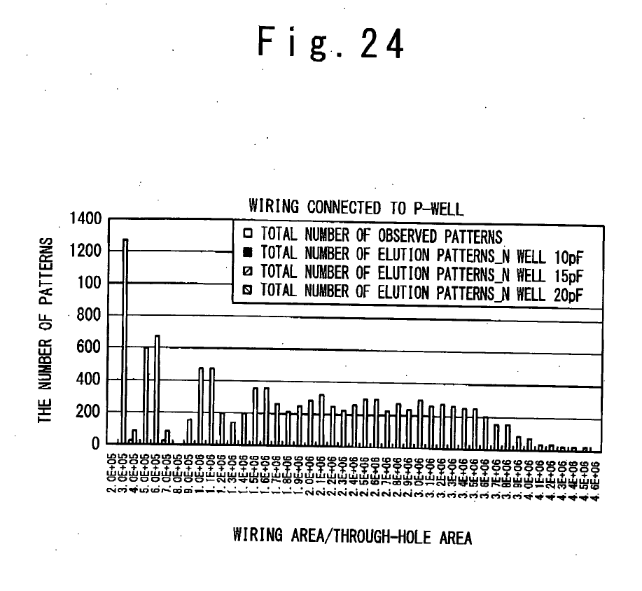

FIGS. 23 and 24 are graphs illustrating a result of the evaluations based on the above-described method. FIGS. 23 and 24 are graphs in the cases where the wiring is connected with the n-type well and where the wiring is connected with the p-type well, respectively. In each of FIGS. 23 and 24, the horizontal axis represents the wiring area, and the vertical axis represents both of the total number of observation patterns and the number of patterns causing the Cu elution.

Note that, even in FIGS. 23 and 24, certain variations of the through-hole area and the wiring area are respectively taken into consideration in diameter and width occurring in lithography, dry etching, and other steps of the manufacturing process, when the wiring area/through-hole area ratio is plotted. As illustrated in FIG. 23, in the case of the n-type well, if the well capacitance exceeds 20 pF, and the wiring area/through-hole area ratio exceeds 2.6×10⁶, an increase in percent defective is observed. As illustrated in FIG. 24, even if the semiconductor device is designed without controlling the wiring area/through-hole area ratio, if a connection to the substrate is made through the p-type well or a low capacitance n-type well, an amount of accumulated electrical charges can be transferred to the substrate, and thereby the Cu elution can be prevented.

### Third Comparative Example

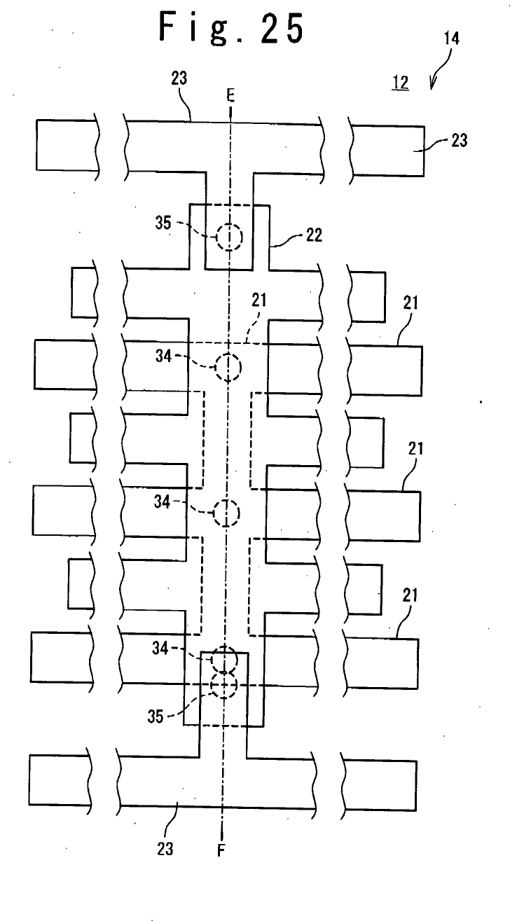

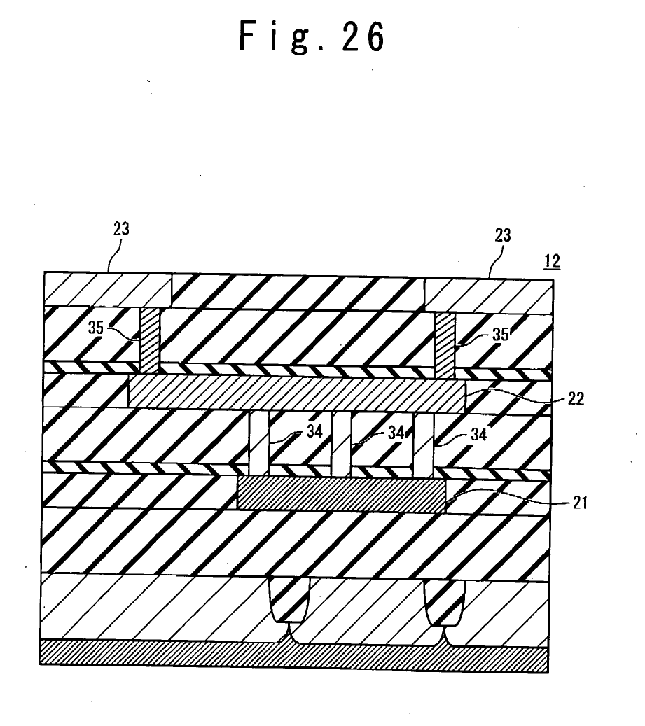

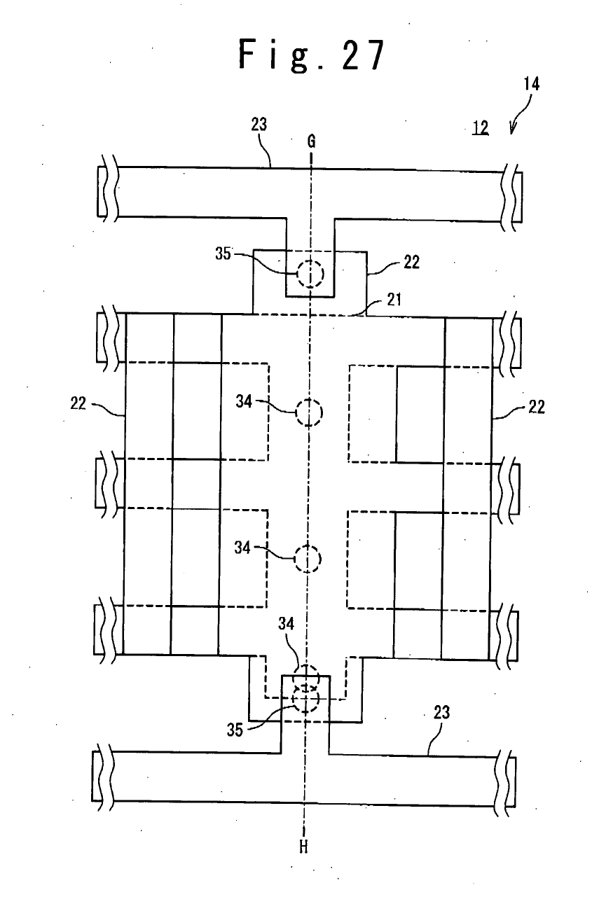

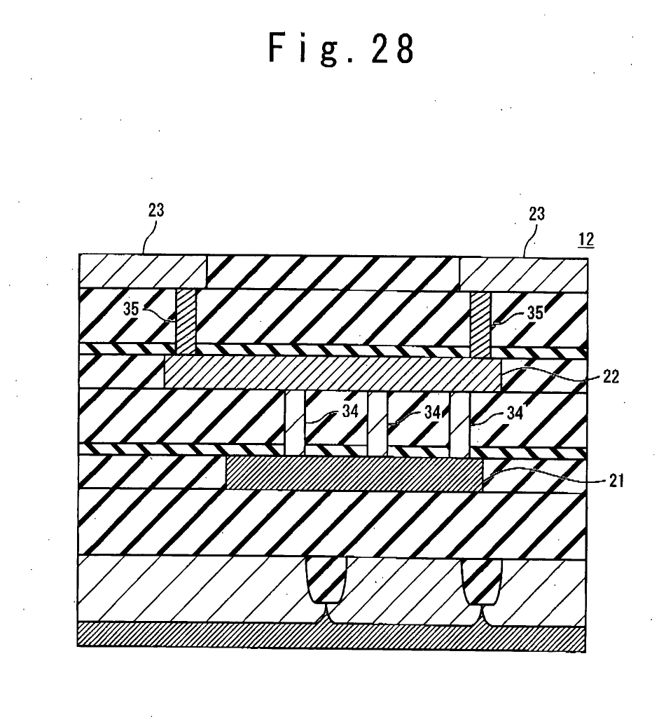

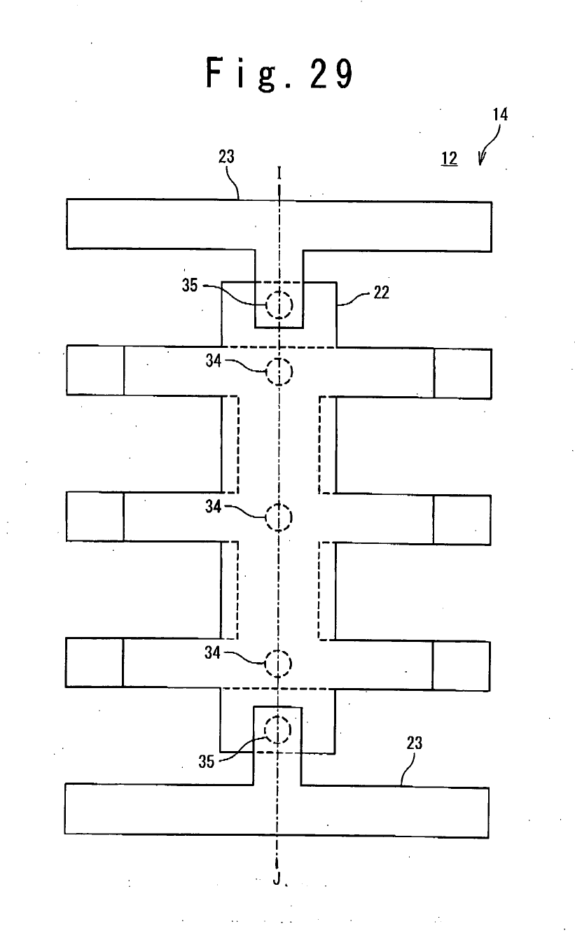

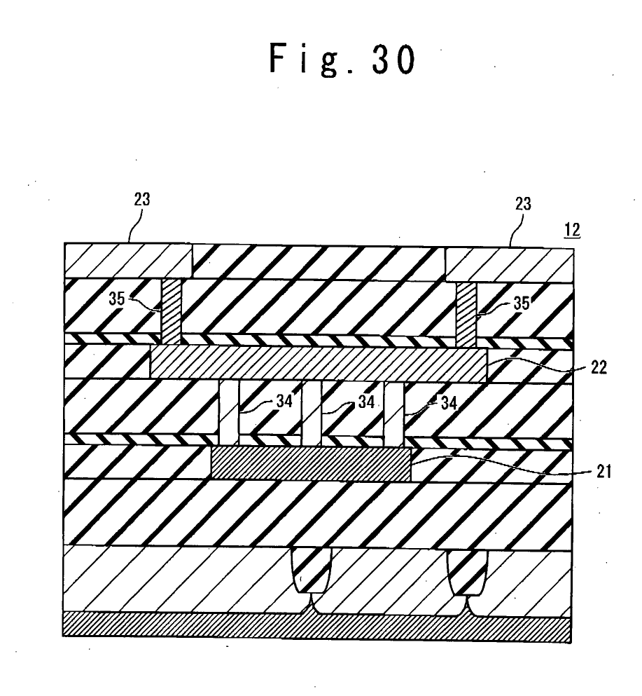

FIGS. 25 to 30 are diagrams exemplifying configurations of the semiconductor integrated circuit 12 in a third comparative example. FIG. 25 is a plan view exemplifying a layout case where, in the semiconductor integrated circuit 12 in the third comparative example, the second metal wiring 22 and the third metal wiring 23 do not overlap with each other. FIG. 26 is across-sectional view exemplifying a configuration of a cross-section of the semiconductor integrated circuit 12 along the line E-F in FIG. 25. FIG. 27 is a plan view exemplifying a layout case where, in the semiconductor integrated circuit 12 in the third comparative example, the second metal wiring 22 and the third metal wiring 23 are arranged perpendicularly to each other. FIG. 28 is a cross-sectional view exemplifying a configuration of a cross section of the semiconductor integrated circuit 12 along the line G-H in FIG. 27. FIG. 29 is a plan view exemplifying a layout case where, in the semiconductor integrated circuit 12 in the third comparative example, the second metal wiring 22 and the third metal wiring 23 are arranged parallel to each other. FIG. 30 is a cross-sectional view exemplifying a configuration of a cross section of the semiconductor integrated circuit 12 along the line I-J in FIG. 29.

In the third comparative example, there are exemplified layout patterns each adapted such that a layer connected to and just below a through-hole (hereinafter referred to as a second layer), and a wiring in a layer that is one layer lower than the second layer (hereinafter referred to as a first layer) have large areas and are in a floating state. In the third comparative example, an elution state of a Cu wiring at the time of chemical solution cleaning and pure water rinsing after etching of the through-hole for forming a second contact hole 35 is evaluated with keeping the above state for each of the layout patterns having different conditions.

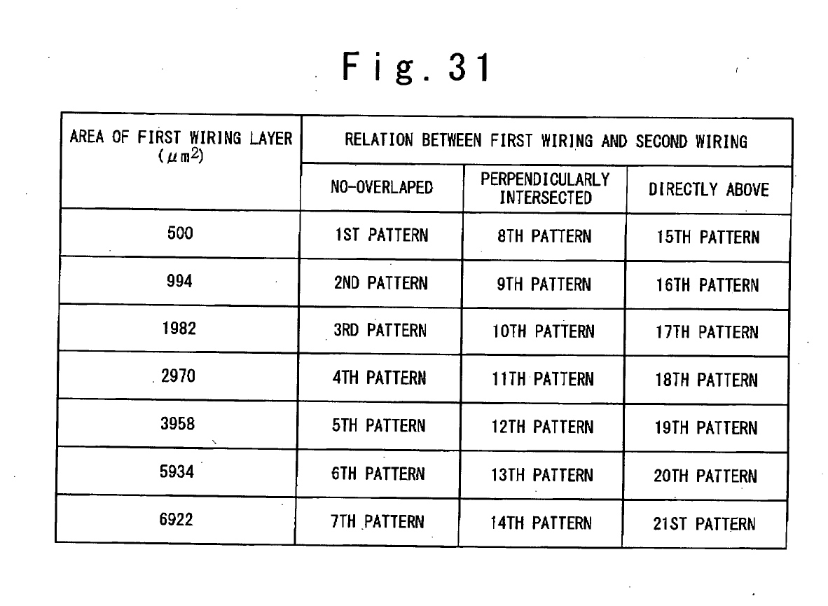

FIG. 31 is a table exemplifying the layout patterns having different conditions used for the evaluations. Note that, as illustrated in FIG. 31, an area of the second layer (second metal wiring 22) is fixed to 3000 μm². Also, an area of a first contact hole 34 making a connection between the second layer (second metal wiring 22) and the first layer (first metal wiring 21) is fixed to 2.0 μm².

As exemplified in FIGS. 25 to 30, the patterns are formed on one and the same wafer such that an overlap area between the first layer (first metal wiring 21) and the second layer (second metal wiring 22) varies. That is, in FIG. 25, there is no overlap between the second layer (second metal wiring 22) and the first layer (first metal wiring 21). On the other hand, in FIG. 27, wiring intervals and wiring widths in the respective wiring layers are the same, and the second layer (second metal wiring 22) and the first layer (first metal wiring 21) are arranged perpendicularly to each other. Specifically, a half of the second metal wiring 22 covers the first metal wiring 21. Further, in FIG. 29, the second layer (second metal wiring 22) is formed so as to completely cover the first layer (first metal wiring 21).

Also, the semiconductor integrated circuit 12 is, similarly to the first comparative example, adapted such that electrical characteristics of the through-hole for the second contact hole 35 can be measured. An etching method for the through-hole and a cleaning method after the etching are the same as those in the above-described comparative examples.

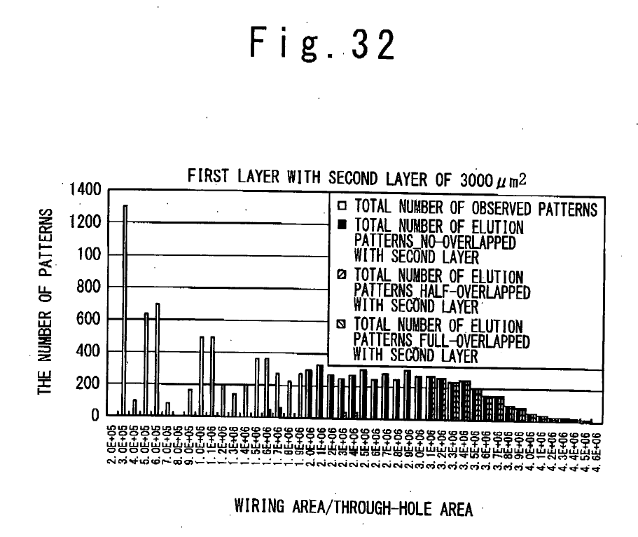

FIG. 32 is a graph illustrating a result of the evaluations in the third comparative example. In FIG. 32, the horizontal axis represents a wiring area of the first layer, and the vertical axis represents a percent defective, for each of the overlap areas between the second layer and the'first layer wiring. Note that, even in FIG. 32, certain variations of the through-hole area and the wiring area are respectively taken into consideration in diameter and width occurring in lithography, dry etching, and other steps of the manufacturing process, when the wiring area/through-hole area ratio is plotted.

In the pattern designed to have almost no overlap between the first and second layers, if the area ratio between the first layer wiring and the through-hole exceeds 1.6×10⁶, an increase in percent defective is observed. Also, in the pattern designed such that a half of the second layer overlaps with the first layer, if the area ratio between the first layer wiring and the through-hole exceeds 2.4×10⁶, an increase in percent defective is observed. Further, in the pattern designed such that the second layer completely overlaps with the first layer, if the area ratio between the first layer wiring and the through-hole exceeds 3.3×10⁶, an increase in percent defective is observed.

An amount of electrical charges generated in an underlying wiring by electrostatic induction due to electrical charges generated by the contact between the chemical solution/pure water/etc. and an interlayer insulating film is inversely proportional to a distance between a surface of the insulating film and the wiring. Accordingly, the layer effectively receiving the largest influence is the second layer that is the layer just below the through hole, and the first layer receives little influence. Also, the electrical charges are accumulated in the second layer, and thereby an electrical circuit, is formed through the through-hole and pure water. For this reason, in the case where the first layer is formed just below the second layer, electrical charges are not accumulated in the first layer. Note that the area of the second layer is limited to 3000 μm², and therefore a defect occurs from a pattern in which the area of the first layer exceeds the second layer overlap of 3000 μm². Accordingly, regarding the control of the wiring area/through-hole area ratio, among underlying wirings, a portion where the other wiring layer is not formed in the insulating film in a step of forming the through-hole is only required to be taken into account.

In the above, the embodiments of the present invention have been specifically described. It is apparent that the present invention is not limited to the above embodiment, but may be modified and changed without departing from the scope and spirit of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A designing method for a semiconductor device comprising:
determining a placement of metal wirings to be connected to contact holes and a placement of through-holes for preparing the contact holes,
wherein the determining step includes:
specifying areas in one of the metal wirings to be exposed by the through-holes,
specifying a capacitance of the metal wirings, and
determining the placement of the metal wirings such that damage to the areas is suppressed in a case where electric charges accumulated in the capacitance are transferred from one of the metal wirings to a polar solvent through the areas.

2. The designing method for a semiconductor device according to claim 1, further comprising:
preliminarily obtaining correlation between a capacitance value of the capacitance of the metal wirings and an occurrence of an elution phenomenon in which wiring material of the metal wirings is eluted; and
determining an upper limit of the capacitance value based on the correlation,
wherein the step of determining the placement of the metal wirings, includes:
determining the placement of the metal wirings such that the capacitance value does not exceed the upper limit.

3. The designing method for a semiconductor device according to claim 1, wherein the step of determining the placement of the metal wirings, includes:
determining, when one of the areas is defined as a reference area, whether an area of one of the metal wirings is equal to or more than 2×10⁶ times as large as the reference area, and
determining the placement of the metal wirings such that the area of the one metal wiring is less than 2×10⁶ times as large as the reference area when the area of the one metal wiring is equal to or more than 2×10⁶ times as large as the reference.

4. The designing method for a semiconductor device according to claim 1, wherein the step of determining the placement of the metal wirings, includes:
determining whether a sum of a well capacitance of a well to be connected to the metal wirings and a wiring capacitance of the metal wirings to be connected to the well is equal to or more than 20 pF, in a case, when one of the areas is defined as the reference area, where an area of one of the metal wirings is equal to or more than 2×10⁶ times as large as the reference area, and
determining the placement of the metal wirings such that the sum is less than 20 pF when the sum is equal to or more than 20 pF.

5. The designing method for a semiconductor device according to claim 1, wherein the step of determining the placement of the metal wirings, includes:
determining a placement of an electric charge supplying circuit supplying electric charges to a substrate, and
determining the placement of the metal wirings such that the damage to the areas is suppressed by supplying the electric charges to the substrate.

6. The designing method for a semiconductor device according to claim 1, wherein the metal wiring includes:
a first wiring, and
a second wiring being placed in a wiring layer different from a wiring layer including the first wiring,
wherein the determining step includes:
determining a placement of the second wiring to be connected to the first wiring through contact holes, and
specifying, when the first wiring is projected to the second wiring, a second wiring portion where a projection of the first wiring does not overlap in the second wiring,
wherein the step of specifying the capacitance of the metal wiring, includes:
specifying a capacitance of the first wiring and the second wiring portion,
wherein the step of determining the placement of the metal wirings, includes:
determining a placement of the first wiring and the second wiring such that the damage to the areas is suppressed in a case where the electric charges are transferred from the first wiring to the polar solvent through the areas.

7. A computer-readable medium including a computer program comprising code operable to control a computer as a semiconductor device designing apparatus, the code comprising:
determining a placement of metal wirings to be connected to contact holes and a placement of through-holes for preparing the contact holes,
wherein the determining step includes:
specifying areas in one of the metal wirings to be exposed by the through-holes,
specifying a capacitance of the metal wirings, and
determining the placement of the metal wirings such that damage to the areas is suppressed in a case where electric charges accumulated in the capacitance are transferred from one of the metal wirings to a polar solvent through the areas.

8. The computer-readable medium according to claim 7, the code further comprising;
preliminarily obtaining correlation between a capacitance value of the capacitance of the metal wirings and an occurrence of an elution phenomenon in which wiring material of the metal wirings is eluted; and
determining an upper limit of the capacitance value based on the correlation,
wherein the step of determining the placement of the metal wirings, includes:
determining the placement of the metal wirings such that the capacitance value does not exceed the upper limit.

9. The computer-readable medium according to claim 7, wherein the step of determining the placement of the metal wirings, includes:
determining, when one of the areas is defined as a reference area, whether an area of one of the metal wirings is equal to or more than 2×10⁶ times as large as the reference area, and
determining the placement of the metal wirings such that the area of the one metal wiring is less than 2×10⁶ times as large as the reference area when the area of the one metal wiring is equal to or more than 2×10⁶ times as large as the reference.

10. The computer-readable medium according to claim 7, wherein the step of determining the placement of the metal wirings, includes:
determining whether a sum of a well capacitance of a well to be connected to the metal wirings and a wiring capacitance of the metal wirings to be connected to the well is equal to or more than 20 pF, in a case, when one of the areas is defined as the reference area, where an area of one of the metal wirings is equal to or more than 2×10⁶ times as large as the reference area, and
determining the placement of the metal wirings such that the sum is less than 20 pF when the sum is equal to or more than 20 pF.

11. The computer-readable medium according to claim 7, wherein the step of determining the placement of the metal wirings, includes:
determining a placement of an electric charge supplying circuit supplying electric charges to a substrate, and
determining the placement of the metal wirings such that the damage to the areas is suppressed by supplying the electric charges to the substrate.

12. The computer-readable medium according to claim 7, wherein the metal wiring includes:
a first wiring, and
a second wiring being placed in a wiring layer different from a wiring layer including the first wiring,
wherein the determining step includes:
determining a placement of the second wiring to be connected to the first wiring through contact holes, and
specifying, when the first wiring is projected to the second wiring, a second wiring portion where a projection of the first wiring does not overlap in the second wiring,
wherein the step of specifying the capacitance of the metal wiring, includes:
specifying a capacitance of the first wiring and the second wiring portion,
wherein the step of determining the placement of the metal wirings, includes:
determining a placement of the first wiring and the second wiring such that the damage to the areas is suppressed in a case where the electric charges are transferred from the first wiring to the polar solvent through the areas.

13. A manufacturing method for a semiconductor device comprising:
designing a semiconductor device; and
producing the semiconductor device based on the designing,
wherein the designing step includes:
determining a placement of metal wirings to be connected to contact holes and a placement of through-holes for preparing the contact holes,
wherein the determining step includes:
specifying areas in one of the metal wirings to be exposed by the through-holes,
specifying a capacitance of the metal wirings, and
determining the placement of the metal wirings such that damage to the areas is suppressed in a case where electric charges accumulated in the capacitance are transferred from one of the metal wirings to a polar solvent through the areas.

14. A semiconductor device comprising:
connecting contacts; and
metal wirings connected to said connecting contacts,
wherein one of said metal wirings includes areas connected to said connecting contacts, and
wherein when each of said areas is defined as a reference area, an area of said one metal wiring is less than 2×10⁶ times as large as said reference area.

15. The semiconductor device according to claim 14, further comprising:
an electric charge supplying circuit supplying electric charges in said metal wirings to a substrate.

16. A semiconductor device comprising:
connecting contacts; and
metal wirings connected to said connecting contacts,
wherein one of said metal wirings includes areas connected to said connecting contacts, and
wherein when each of said areas is defined as a reference area, an area of said one metal wiring is equal to or more than 2×10⁶ times as large as said reference area, and
wherein a sum of a well capacitance of a well to be connected to said metal wirings and a wiring capacitance of said metal wirings to be connected to said well is less than 20 pF.

17. The semiconductor device according to claim 16, further comprising:
an electric charge supplying circuit supplying electric charges in said metal wirings to a substrate.
